(19) United States
(12) Patent Application Publication
(10) Pub. No.: US 2021/0280925 A1
(43) Pub. Date: Sep. 9, 2021

(54) DEVICE TEMPERATURE REGULATOR

(71) Applicant: DENSO CORPORATION, Kariya-city, Aichi-pref. (JP)

(72) Inventors: Takeshi YOSHINORI, Kariya-city (JP); Takashi YAMANAKA, Kariya-city (JP); Yoshiki KATO, Kariya-city (JP); Masayuki TAKEUCHI, Kariya-city (JP); Koji MIURA, Kariya-city (JP); Yasumitsu OMI, Kariya-city (JP)

(21) Appl. No.: 16/330,440

(22) PCT Filed: Aug. 2, 2017
(86) PCT No.: PCT/JP2017/028059

§ 371 Date: Mar. 5, 2019

(30) Foreign Application Priority Data
Sep. 9, 2016 (JP) 2016-176790

(51) Int. Cl. H01M 10/625; H01M 10/63; H01M 10/613; H01M 10/615; H01M 10/6564; H01M 10/6568

(52) U.S. Cl. CPC H01M 10/625; H01M 10/63; H01M 10/6568; H01M 10/615; H01M 10/6564; H01M 10/613

(57) ABSTRACT

In a device temperature regulator, an evaporator cools a target device by a latent heat of evaporation of a working fluid that absorbs heat from the target device and is evaporated. A first condenser includes a first heat exchange passage that condenses the working fluid evaporated in the evaporator by a heat exchange with an outside first medium. A second condenser includes a second heat exchange passage that condenses the working fluid evaporated in the evaporator by a heat exchange with an outside second medium. A gas-phase passage causes the working fluid evaporated in the evaporator to flow to the first condenser and the second condenser. Furthermore, a first liquid-phase passage causes the working fluid condensed in the first condenser to flow to the evaporator, and a second liquid-phase passage causes the working fluid condensed in the second condenser to flow to the evaporator.

### CROSS REFERENCE TO RELATED APPLICATION

This application is based on Japanese Patent Application No. 2016-176790 filed on Sep. 9, 2016, the contents of which are incorporated herein by reference in its entirety.

### FIELD OF THE INVENTION

The present disclosure relates to a device temperature regulator that regulates a temperature of a target device.

### BACKGROUND ART

In recent years, a technique of using thermosiphon has been studied as a device temperature regulator designed to regulate a temperature of an electric device such as an electrical storage device mounted on an electrically-driven vehicle, for example, an electric vehicle or a hybrid vehicle.

A device temperature regulator described in Patent Document 1 includes an evaporator provided on a side surface of a battery as the electrical storage device and a condenser provided above the evaporator. The evaporator and the condenser are annularly connected by two pipes and has a refrigerant as a working fluid enclosed therein. In the device temperature regulator, when the battery generates heat, a liquid-phase refrigerant in the evaporator boils and consequently the battery is cooled by a latent heat of evaporation at that time. The gas-phase refrigerant generated in the evaporator flows through a gas-phase passage formed by one of the two pipes and flows into the condenser. In the condenser, the gas-phase refrigerant is condensed by a heat exchange with an external medium located on the outside of the condenser. The liquid-phase refrigerant generated in the condenser flows by gravity through the liquid-phase passage formed by the other of the two pipes and then flows into the evaporator. The battery of the target device is cooled by such natural circulation of the refrigerant.

In the present specification, the device temperature regulator implies the whole of a device that regulates a temperature of a target device by a thermosiphon system. In other words, the device temperature regulator includes any device that only cools the target device, that only heats the target device, or that both cools and heats the target device.

### RELATED ART DOCUMENTS

### Patent Document

Patent Document 1: Japanese Unexamined Patent Application Publication No. 2015-041418

### SUMMARY OF INVENTION

The device temperature regulator described in Patent Document 1 includes only one condenser. For this reason, it can be thought that when the amount of heat generated by the battery becomes large, the liquid-phase refrigerant necessary for cooing the battery is not sufficiently fed to the evaporator from the condenser. Further, in a case where the device temperature regulator is assumed to include a plurality of condensers, in order to prevent the refrigerant brought into a liquid phase in one condenser from being again heated by the other condenser, it is preferable that a temperature of environment in which the plurality of condensers are arranged and a position in which the plurality of condensers are arranged are suitably set. In other words, the device temperature regulator of the thermosiphon system circulates the refrigerant by using an own weight of the liquid-phase refrigerant as a driving force, so that in order to improve a cooling capacity of the target device, it is important to efficiently feed the working fluid of a liquid phase to the evaporator from the condensers.

It is an objective of the present disclosure to provide a device temperature regulator that can efficiently feed an evaporator with a liquid-phase working fluid and that can prevent the working fluid from being again heated.

According to an aspect of the present disclosure, a device temperature regulator for regulating a temperature of a target device includes an evaporator, a first condenser, a second condenser, a gas-phase passage, a first liquid-phase passage, and a second liquid-phase passage. The evaporator is configured to cool the target device by latent heat of evaporation of a working fluid by absorbing heat from the target device to be evaporated. The first condenser is provided on an upper side in a gravitational direction than the evaporator and includes a first heat exchange passage to condense the working fluid evaporated in the evaporator by a heat exchange with a first medium outside of the first condenser. The second condenser is provided on an upper side in the gravitational direction than the evaporator and that includes a second heat exchange passage to condense the working fluid evaporated in the evaporator by a heat exchange with a second medium outside of the second condenser. The gas-phase passage causes the working fluid evaporated in the evaporator to flow to the first condenser and the second condenser. The first liquid-phase passage extends from the first condenser and causes the working fluid condensed in the first condenser to flow to the evaporator. The second liquid-phase passage extends from the second condenser and causes the working fluid condensed in the second condenser to flow to the evaporator.

Thus, the first condenser and the second condenser are connected to each other in parallel by the gas-phase passage and by the liquid-phase passage. Of the first condenser and the second condenser, the condenser that is higher in a capacity of condensing the working fluid is smaller in a pressure loss of a flow of the working fluid than the condenser that is lower in the capacity. For this reason, of the first condenser and the second condenser, the condenser that is higher in the capacity of condensing the working fluid can increase a flow rate of the working fluid and can generate the more working fluid of the liquid phase without being restricted in the flow of the working fluid by the condenser that is lower in the capacity. Thus, the device temperature regulator can efficiently feed the working fluid of the liquid phase to the evaporator from the condenser in which the capacity of condensing the working fluid is higher.

Further, the first condenser and the second condenser are connected to each other in parallel, so the working fluid of the liquid phase generated in one condenser flows to the evaporator without passing through the other condenser. For this reason, of the first condenser and the second condenser, the liquid-phase refrigerant generated in the condenser in which the capacity for condensing the working fluid is higher is prevented from being again heated by the other condenser in which the capacity for condensing the working fluid is lower. Thus, the device temperature regulator can efficiently use energy for cooling the working fluid in the first condenser and the second condenser and can increase the flow rate of the working fluid of the liquid phase which is to be fed to the evaporator from the first condenser and the second condenser.

### BRIEF DESCRIPTION OF THE DRAWINGS

FIG. 1 is a configuration diagram of a device temperature regulator according to a first embodiment.

FIG. 2 is a partially enlarged view of the device temperature regulator according to the first embodiment.

FIG. 3 is a partially enlarged view of a device temperature regulator according to a second embodiment.

FIG. 4 is a configuration diagram of a device temperature regulator according to a third embodiment.

FIG. 5 is a configuration diagram of a device temperature regulator according to a first reference example.

FIG. 6 is a configuration diagram of a device temperature regulator according to a fourth embodiment.

FIG. 7 is a configuration diagram of a device temperature regulator according to a second reference example.

FIG. 8 is a partially enlarged view of a device temperature regulator according to a fifth embodiment.

FIG. 9 is a partially enlarged view of a device temperature regulator according to a sixth embodiment.

FIG. 10 is a partially enlarged view of a device temperature regulator according to a seventh embodiment.

FIG. 11 is a partially enlarged view of a device temperature regulator according to an eighth embodiment.

FIG. 12 is a partially enlarged view of a device temperature regulator according to a ninth embodiment.

FIG. 13 is a partially enlarged view of a device temperature regulator according to a tenth embodiment.

### DESCRIPTION OF EMBODIMENTS

Hereinafter, embodiments of the present disclosure will be described with reference to the accompanying drawings. In the respective embodiments below, the same or equivalent parts will be described with the same reference characters. In the drawings, when the same configuration is shown in a plurality of sites, only some of them will be denoted by the reference characters.

### First Embodiment

A first embodiment will be described with reference to the accompanying drawings. A device temperature regulator of the present embodiment cools a target device, i.e., an electric device, such as an electrical storage device or an electronic circuit, mounted on an electrically driven vehicle such as an electric vehicle and a hybrid vehicle, thereby regulating a temperature of the target device. In the drawings, arrows indicting up and down represent upward and downward in a gravitational direction when the device temperature regulator is mounted on a vehicle and the vehicle is stopped at a horizontal plane.

First, the target device having a temperature regulated by a device temperature regulator 1 of the present embodiment will be described.

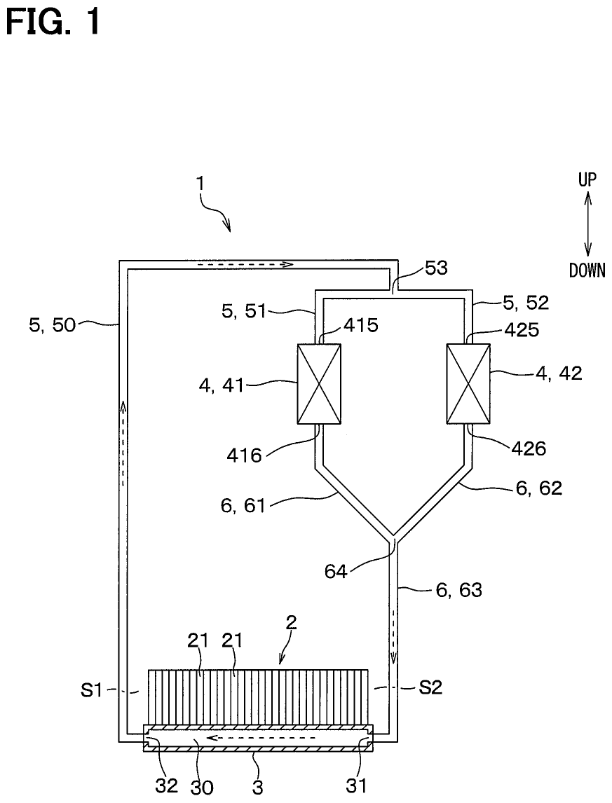

As shown in FIG. 1, the target device having a temperature regulated by the device temperature regulator 1 of the present embodiment is an assembled battery 2 (hereinafter referred to as a “battery”). The target device may be a battery pack that includes the battery 2, a power converter (not shown in the figure), and the like.

The battery 2 is used as a power source for a vehicle, such as an electric vehicle and a hybrid vehicle, which can travel using a traveling electric motor. The battery 2 is configured of a stack of a plurality of battery cells 21 each having a rectangular parallelepiped shape. The plurality of battery cells 21 configuring the battery 2 is electrically connected to each other in series. Each battery cell 21 is configured of, for example, a rechargeable-dischargeable secondary battery, such as a lithium ion battery or a lead acid battery. The battery cell 21 is not limited to the rectangular parallelepiped shape and may be have any other shape, such as a cylindrical shape. The battery 2 may include battery cells 21 electrically connected in parallel.

The battery 2 is connected to a power converter (not shown) and a motor generator (not shown) which are included in the vehicle. The power converter is, for example, a device that converts a DC current supplied from the battery 2 into an AC current and discharges the converted AC current to various electric loads, such as the traveling electric motor. Further, the motor generator is a device that inversely converts a traveling energy of the vehicle into an electric energy during a regenerative braking of the vehicle and supplies the inversely converted electric energy as a regenerative electric power to the battery 1 via an inverter or the like.

The battery 2 self-generates heat when supplying the electric power or the like while the vehicle is traveling and, consequently, the battery 2 is brought into an extremely high temperature in some cases. When the battery 2 reaches the extremely high temperature, a deterioration of the battery cells 21 is accelerated. Thus, an output and input of the battery 2 need to be restricted so as to reduce the self-generated heat. In order to secure the output and input of the battery cells 21, a cooling means for maintaining the temperature of the battery 2 at a predetermined temperature or lower is required.

The electrical storage device including the battery 21 is often disposed under a floor of the vehicle or under a trunk room. Thus, the temperature of the battery 2 gradually increases not only during traveling of the vehicle, but also during parking or the like in summer, and eventually the battery 2 reaches an extremely high temperature in some cases. When the battery 2 is left under a high temperature environment, the deterioration of the battery 2 is accelerated, and thus its lifetime is significantly reduced. Because of this, the temperature of the battery 2 is desired to be maintained at a predetermined temperature or lower even during parking of the vehicle or the like.

Further, as the battery 2 includes the configuration of the respective battery cells 21 electrically connected in series, the input and output characteristics of the entire battery are determined depending on the state of the battery 21 that deteriorates the most among the respective battery cells 21. Thus, when there is a variation in the temperatures of the respective battery cells 21, the progression of deterioration of the respective battery cells 21 is biased, which hence degrades the input and output characteristics of the entire battery. Therefore, in order to cause the battery 2 to exhibit a desired performance for a long time, it is important to reduce the variation in the temperatures of the respective battery cells 21, that is, to equalize the temperature of each battery cell 21.

In general, an air-cooled cooling means by a blower, a cooling means by a coolant, or a cooling means using a refrigeration cycle of a vapor compression type is employed as a cooling means for cooling the battery 2.

However, the air-cooled cooling means by the blower only blows the air inside or outside a vehicle compartment to the battery 2 and consequently cannot gain a sufficient cooling capacity to cool the battery 2 in some cases. In the air-cooled cooling means or the cooling means by the coolant, variations are caused in the cooling temperature between the battery cell 21 on an upstream side of an air or coolant flow and the battery cell 21 on a downstream side thereof in some cases.

The cooling means using cold heat in the refrigeration cycle has a high cooling capacity of the battery 2 but needs to drive a compressor or the like that has a large power consumption during parking of the vehicle. This might lead to an increase in power consumption and an increase in noise.

Hence, the device temperature regulator 1 of the present embodiment does not force a refrigerant as a working fluid to circulate by using the compressor but employs a thermosiphon system which regulates the temperature of the battery 2 by using the natural circulation of the refrigerant.

Next, a configuration of the device temperature regulator 1 will be described.

As shown in FIG. 1, the device temperature regulator 1 includes an evaporator 3, a first condenser 41, a second condenser 42, a gas-phase passage 5, a liquid-phase passage 6, and the like, and these constituent members are connected to each other to configure a loop-type thermosiphon. The device temperature regulator 1 has a predetermined amount of refrigerant enclosed therein with its interior evacuated. As the refrigerant, various kinds of materials such as R134a, R1234yf, carbon dioxide, and water can be employed. As indicated by the dot-and-dash lines S1 and S2 in FIG. 1, the amount of the refrigerant is preferably set such that the upper liquid surface of the liquid-phase refrigerant is located at some point of the gas-phase passage 5 and at some point of the liquid-phase passage 6 before the cooling of the battery 2 is started. When the refrigerant is circulated in a direction indicated by the dashed arrow in FIG. 1, the upper liquid surface of the liquid-phase refrigerant is displaced accordingly.

The evaporator 3 is a hermetically sealed case and is formed in a flat shape and is provided in a position facing a lower surface of the battery 2. The evaporator 3 is preferably made of a material having an excellent thermal conductivity, such as aluminum or copper. The evaporator 3 may be provided to enable heat transfer between the plurality of battery cells 21 and the evaporator 3. For example, the evaporator 3 may be provided in a position that faces a side surface or an upper surface of the battery 2. A shape and a size of the battery 3 can be arbitrarily set in accordance with a space of the vehicle where the evaporator 3 is mounted.

The evaporator 3 has a fluid chamber 30 inside. The fluid chamber 30 is preferably filled with the liquid-phase refrigerant before the cooling of the battery 2 is started. Actually, the liquid-phase refrigerant and the gas-phase refrigerant may be included in the fluid chamber 30. When the battery 2 self-generates heat due to electric storage, electric discharge, or the like, the heat is transferred from the battery 2 to the evaporator 3, and subsequently the liquid-phase refrigerant in the fluid chamber 30 absorbs heat to evaporate. At that time, the liquid-phase refrigerant evaporates within the entire fluid chamber 30, so that the plurality of battery cells 21 are cooled substantially uniformly by a latent heat of evaporation. Therefore, the evaporator 3 can reduce variations in the temperature among the battery cells 21 to equalize the temperatures of the plurality of battery cells 21 and can also cool the battery cells 21.

As described above, when the battery 2 is brought into the high temperature, the battery 2 cannot exhibit sufficient functions and is impaired or damaged in some cases. The battery 2 has its input and output characteristics determined as a whole in accordance with the characteristics of the most impaired battery cell 21. For this reason, the evaporator 3 equalizes the temperatures of the plurality of battery cells 21 by cooling using the latent heat of evaporation and thereby cools the battery cells 21, which hence enables the battery 2 to exhibit the desired performance for a long period of time.

The gas-phase passage 5 and the liquid phase passage 6 are connected to the evaporator 3. A portion where the evaporator 3 and the liquid-phase passage 6 are connected is referred to as a first opening 31, whereas a portion where the evaporator 3 and the gas-phase passage 5 are connected is referred to as a second opening 32. In the evaporator 3, the first opening 31 and the second opening 32 are preferably spaced apart from each other. Thus, when the refrigerant is circulated through a thermosiphon loop, a flow of the refrigerant directed from the first opening 31 to the second opening 32 is generated in the evaporator 3. In FIG. 1, both of the first opening 31 and the second opening 32 are provided on the side surfaces of the evaporator 3, but the positions of the first opening 31 and the second opening 32 are not limited to the side surfaces and may be either an upper surface or a lower surface of the evaporator 3.

The condenser 4 is configured so as to include a first condenser 41 and a second condenser 42. The first condenser 41 has a function of condensing the refrigerant flowing in its inside passage by a heat exchange with a medium (not shown in the figure) located on the outside of the first condenser 41. In the following description, the medium located on the outside of the first condenser 41 is referred to as a fist medium. The second condenser 42 also has a function of condensing the refrigerant flowing in its inside passage by a heat exchange with a medium (not shown in the figure) located on the outside of the second condenser 42. In the following description, the medium located on the outside of the second condenser 42 is referred to as a second medium. The first medium and the second medium can have their temperatures set individually. In the first embodiment to a third embodiment and a first reference example, the first medium and the second medium may be the same kind of medium or may be different kinds of media.

Both of the first condenser 41 and the second condenser 42 are provided on an upper side in the gravitational direction than the evaporator 3. The first condenser 41 and the second condenser 42 are connected to each other in parallel by the gas-phase passage 5 and by the liquid-phase passage 6.

The gas-phase passage 5 is configured so as to include an evaporator side gas-phase passage 50 extending from the evaporator 3, a first gas-phase passage 51 extending from the first condenser 41, and a second gas-phase passage 52 extending from the second condenser 42. An end portion on a side opposite to the evaporator 3 of the evaporator side gas-phase passage 50, an end portion on a side opposite to the first condenser 41 of the first gas-phase passage 51, and an end portion on a side opposite to the second condenser 42 of the second gas-phase passage 52 are connected to each other by a branch portion 53.

In more detail, the evaporator side gas-phase passage 50 has its one end connected to a second opening portion 32 of the evaporator 3 and has its other end connected to the branch portion 53. The first gas-phase passage 51 has its one end connected to the branch portion 53 and has its other end connected to a first inlet portion 415 of the first condenser 41. The second gas-phase passage 52 has its one end connected to the branch portion 53 and has its other end connected to a second inlet portion 425 of the second condenser 42. In this way, the gas-phase passage 5 can cause a gas-phase refrigerant evaporated in the evaporator 3 to flow to the first condenser 41 and to the second condenser 42. The gas-phase refrigerant mainly flows in the gas-phase passage 5, but a refrigerant in a gas-liquid two-phase state or a liquid-phase refrigerant flows in the gas-phase passage 5 in some cases.

The liquid-phase passage 6 is configured so as to include a first liquid-phase passage 61 extending from the first condenser 41, a second liquid-phase passage 62 extending from the second condenser 42, and a third liquid-phase passage 63 extending from the evaporator 3. An end portion on a side opposite to the first condenser 41 of the first liquid-phase passage 61, an end portion on a side opposite to the second condenser 42 of the second liquid-phase passage 62, and an end portion on a side opposite to the evaporator 3 of the third liquid-phase passage 63 are connected to each other at a collection portion 64.

In more details, the first liquid-phase passage 61 has its one end connected to a first outlet portion 416 of the first condenser 41 and has its other end connected to the collection portion 64. The first liquid-phase passage 61 causes the liquid-phase refrigerant condensed in the first condenser 41 to flow toward the evaporator 3. The second liquid-phase passage 62 has its one end connected to a second outlet portion 426 of the second condenser 42 and has its other end connected to the collection portion 64. The second liquid-phase passage 62 causes the liquid-phase refrigerant condensed in the second condenser 42 to flow toward the evaporator 3. In the collection portion 64, the liquid-phase refrigerant flowing in the first liquid-phase passage 61 and the liquid-phase refrigerant flowing in the second liquid-phase passage 62 collect. The third liquid-phase passage 63 has its one end connected to the collection portion 64 and has its other end connected to the first opening portion 31 of the evaporator 3. In the third liquid-phase passage 63, the liquid-phase refrigerant, which flows in the first liquid-phase passage 61 and the second liquid-phase passage 62 and collects in the collection portion 64, flows to the evaporator 3. In this way, the liquid-phase passage 6 can cause the liquid-phase refrigerant condensed in the first condenser 41 and the second condenser 42 to flow to the evaporator 3 by the gravity. Here, in the liquid-phase passage 6, the liquid-phase refrigerant mainly flows, but the refrigerant in the gas-liquid two-phase state or the gas-phase refrigerant flows in some cases.

Subsequently, the first condenser 41 and the second condenser 42 will be described in detail.

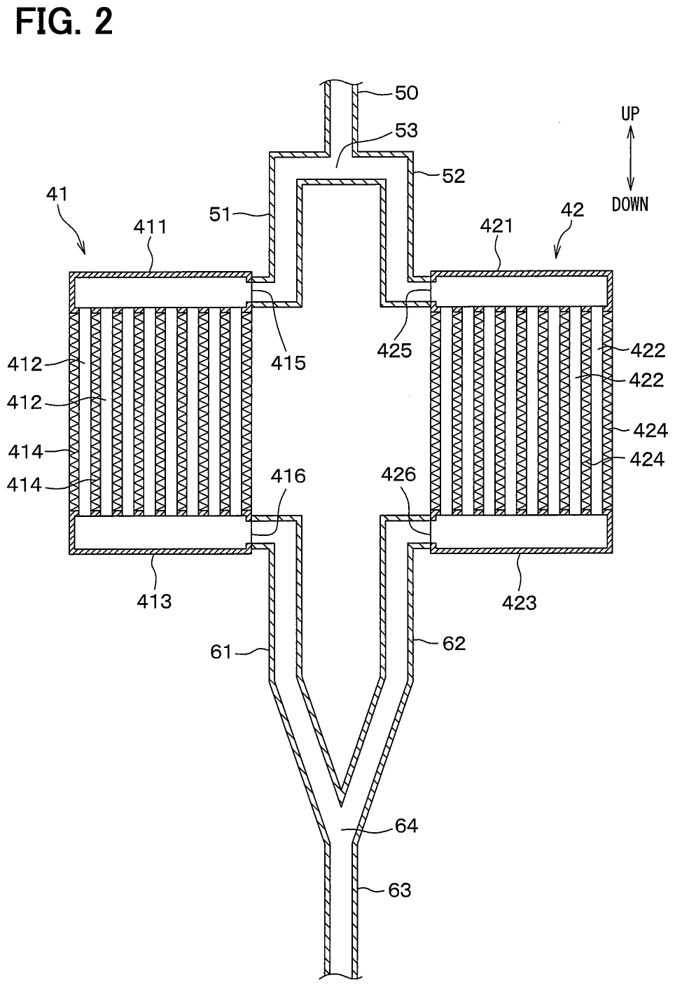

As shown in FIG. 2, the first condenser 41 includes a first upper tank 411, a plurality of first heat exchange tubes 412, and a first lower tank 413. The first condenser 41 is preferably formed of a material having an excellent thermal conductivity, for example, aluminum or copper. The shape and size of the first condenser 41 can be arbitrarily set in accordance with a space of the vehicle where the first condenser 41 is mounted.

The plurality of first heat exchange tubes 412 correspond to first heat exchange passages which condense the gas-phase refrigerant by a heat exchange with the first medium. A plurality of fins 414 is provided on each of the first heat exchange tubes 412. The plurality of first heat exchange tubes 412 extend along the gravitational direction. In this way, the liquid-phase refrigerant flows along the gravitational direction inside the plurality of first heat exchange tubes 412.

The gas-phase refrigerant, which flows into the first inlet portion 415 from the first gas-phase passage 51 and is fed to the first upper tank 411, flows into the plurality of first heat exchange tubes 412 from the first upper tank 411. When the gas-phase refrigerant flows in the plurality of first heat exchange tubes 412, the gas-phase refrigerant is condensed by a heat exchange with a first medium located on the outside of the first condenser 41. The liquid-phase refrigerant generated in the plurality of first heat exchange tubes 412 flows into the first lower tank 413 by its own weight. The liquid-phase refrigerant flows from the first outlet portion 416 formed in the first lower tank 413 to the evaporator 3 through the first liquid-phase passage 61, the collection portion 64, and the third liquid-phase passage 63.

The second condenser 42 also has a second upper tank 421, a plurality of second heat exchange tubes 422, and a second lower tank 423. The second condenser 42 also is preferably formed of a material having an excellent thermal conductivity, for example, aluminum or copper. The shape and size of the second condenser 42 can be arbitrarily set in accordance with a space of the vehicle where the second condenser 42 is mounted

The plurality of second heat exchange tubes 422 correspond to second heat exchange passages which condense the gas-phase refrigerant by a heat exchange with the second medium. A plurality of fins 424 are provided on each of the second heat exchange tubes 422. The plurality of second heat exchange tubes 422 extend along the gravitational direction. In this way, the liquid-phase refrigerant flows along the gravitational direction inside the plurality of second heat exchange tubes 422.

The gas-phase refrigerant, which flows in the second inlet portion 425 from the second gas-phase passage 52 and is fed to the second upper tank 421, flows in the plurality of second heat exchange tubes 422 from the second upper tank 421. When the gas-phase refrigerant flows in the plurality of second heat exchange tubes 422, the gas-phase refrigerant is condensed by a heat exchange with a second medium located on the outside of the second condenser 42. The liquid-phase refrigerant generated in the plurality of second heat exchange tubes 422 flows into the second lower tank 423 by its own weight. The liquid-phase refrigerant flows from a second outlet portion 426 formed in the second lower tank 423 to the evaporator 3 through the second liquid-phase passage 62, the collection portion 64, and the third liquid-phase passage 63.

The device temperature regulator 1 of the first embodiment has the configuration described above and hence has the following operations and effects.

(1) In the first embodiment, the first condenser 41 and the second condenser 42 are connected to each other in parallel by the gas-phase passage 5 and by the liquid-phase passage 6. In this way, of the first condenser 41 and the second condenser 42, the condenser which is higher in a capacity of condensing the refrigerant is smaller in a pressure loss than the condenser which is lower in the capacity of condensing the refrigerant. For this reason, of the first condenser 41 and the second condenser 42, the condenser which is higher in the capacity of condensing the refrigerant can increase a flow rate of the refrigerant without being restricted in the flow of the refrigerant by the condenser which is lower in the capacity and hence can generate the more amount of liquid-phase refrigerant. Hence, the device temperature regulator 1 can efficiently feed the refrigerant to the evaporator 3 from the condenser which is higher in the capacity of condensing the refrigerant.

Further, in the first embodiment, the first condenser 41 and the second condenser 42 are connected to each other in parallel, so the liquid-phase refrigerant generated in one condenser is fed to the evaporator 3 without passing through the other condenser. For this reason, the liquid-phase refrigerant generated in the condenser, which is higher in the capacity of condensing the refrigerant, of the first condenser 41 and the second condenser 42 can be prevented from being again heated by the condenser which is lower in the capacity. Thus, the device temperature regulator 1 can efficiently use energy for cooling the refrigerant in the first condenser 41 and the second condenser 42 and can increase a flow rate of the liquid-phase refrigerant to be fed to the evaporator 3 from the first condenser 41 and the second condenser 42.

(2) In the first embodiment, the first medium located on the outside of the first condenser 41 and the second medium located on the outside of the second condenser 42 can have their temperatures set individually.

According this, it can be said that in the first medium and the second medium, a temperature of one medium and a temperature of the other medium do not have an effect on each other, that is, the first medium and the second medium are thermally independent from each other. For this reason, for example, when the amount of heat generated by the battery 2 is large, by using the medium whose temperature is lower of the first medium and the second medium, the production of the liquid-phase refrigerant can be increased and the battery 2 can be sufficiently cooled. On the other hand, when the amount of heat generated by the battery 2 is small, by using the medium whose temperature is higher of the first medium and the second medium, the battery 2 can be cooled to a suitable temperature. Thus, the device temperature regulator can perform a temperature regulation according to the amount of heat generated by the battery 2.

(3) In the first embodiment, the plurality of first heat exchange tubes 412 included by the first condenser 41 and the plurality of second heat exchange tubes 422 included by the second condenser 42 extend along the gravitational direction.

According to this, the plurality of first heat exchange tubes 412 and the plurality of second heat exchange tubes 422 can cause the liquid-phase refrigerant to flow downward in the gravitational direction by the own weight of the liquid-phase refrigerant. Hence, the device temperature regulator 1 can smoothly circulate the refrigerant and can improve a cooling capacity of the battery 2.

### Second Embodiment

A second embodiment will be described. The second embodiment has an arrangement of the second condenser 42 changed with respect to the first embodiment and is the same as the first embodiment in the other parts, and hence only differences from the first embodiment will be described.

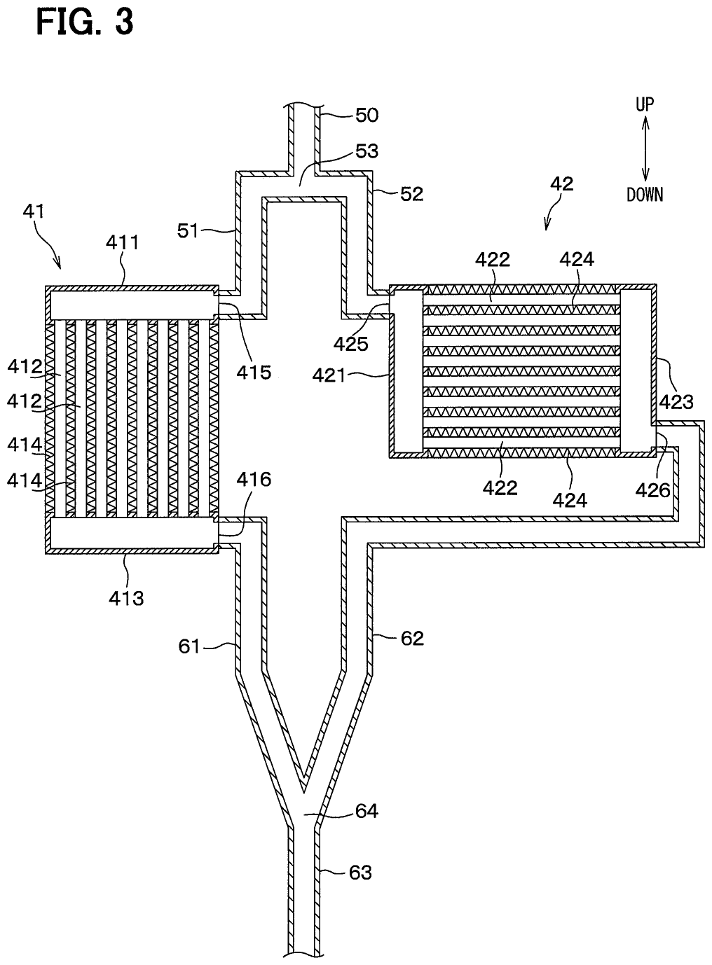

As shown in FIG. 3, in the second embodiment, the plurality of heat exchange tubes 422 included by the second condenser 42 extend in a direction crossing the gravitational direction. Here, the second upper tank 421 and the second lower tank 423 which are included by the second condenser 42 extend along the gravitational direction.

On the other hand, the plurality of first heat exchange tubes 412 included by the first condenser 41 extend along the gravitational direction. In this way, a force by which the liquid-phase refrigerant flows along the gravitational direction inside the plurality of first heat exchange tubes 412 becomes larger.

In the second embodiment, the liquid-phase refrigerant generated by the plurality of first heat exchange tubes 412 of the first condenser 41 becomes larger in a force flowing along the gravitational direction by its own weight and smoothly flows from the first lower tank 413 to the evaporator 3 via the first liquid-phase passage 61, the collection portion 64, and the third liquid-phase passage 63. On the other hand, the second condenser 42 is weaker than the first condenser 41 in a force by which the liquid-phase refrigerant flows, but the liquid-phase refrigerant generated by the plurality of second heat exchange tubes 422 flows from the second upper tank 421 to the second lower tank 423 and then smoothly flows to the evaporator 3 via the second liquid-phase passage 62, the collection portion 64, and the third liquid-phase passage 63. This can suppress the liquid-phase refrigerant or air bubbles from flowing backward from the evaporator 3. Thus, the device temperature regulator 1 can improve the cooling capacity of the battery 2.

### Third Embodiment

A third embodiment will be described. The third embodiment has an arrangement of the two condensers and a configuration of the liquid-phase passage 6 changed with respect to the first embodiment and is the same as the first embodiment in the other parts, and hence only differences from the first embodiment will be mainly described.

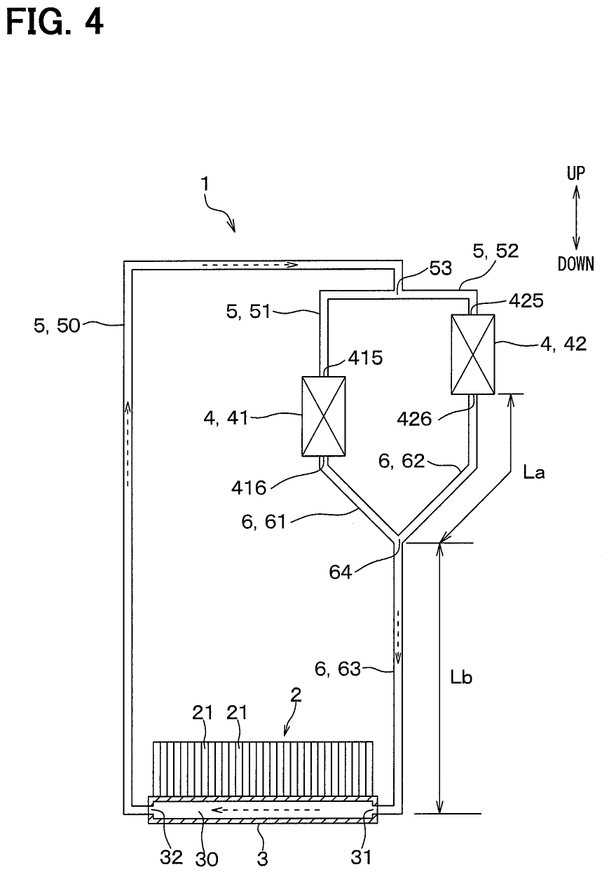

As shown in FIG. 4, in the third embodiment, the second outlet portion 426 included by the second condenser 42 is arranged on an upper side in the gravitational direction than the first outlet portion 416 included by the first condenser 41. In other words, a position in which the second liquid-phase passage 62 is connected to the second outlet portion 426 of the second condenser 42 is higher in the gravitational direction than a position in which first liquid-phase passage 61 is connected to the first outlet portion 416 of the first condenser 41. Here, of the first liquid-phase passage 61 and the second liquid-phase passage 62, a length of the liquid-phase passage which is higher between a position in which the first liquid-phase passage 61 is connected to the first condenser 41 and a position in which the second liquid-phase passage 62 is connected to the second condenser 42 will be denoted by La. A length of the third liquid-phase passage 63 will be denoted by Lb. Further, of the first liquid-phase passage 61 and the second liquid-phase passage 62, a volume of the liquid-phase passage which is higher between the position in which the first liquid-phase passage 61 is connected to the first condenser 41 and the position in which the second liquid-phase passage 62 is connected to the second condenser 42 will be denoted by Va. A volume of the third liquid-phase passage 63 will be denoted by Vb. Here, inside diameters of the first to third liquid-phase passages 61, 62, 63 are nearly equal. In the third embodiment, the length of the second liquid-phase passage 62 which is higher in the position in which the second liquid-phase passage 62 is connected to the second condenser 42 corresponds to La, and the volume of the second liquid-phase passage 62 corresponds to Va.

At this time, a relation between the length La of the second liquid-phase passage 62 and the length Lb of the third liquid-phase passage 63 is La<Lb. Further, a relation between the volume Va of the second liquid-phase passage 62 and the volume Vb of the third liquid-phase passage 63 is Va<Vb.

In the third embodiment, the second liquid-phase passage 62 and the third liquid-phase passage 63 have a relation of La<Lb, so the liquid-phase refrigerant flowing in the second liquid-phase passage 62 is suppressed from flowing backward to the first liquid-phase passage 61 near the collection portion 64 and hence smoothly flows to the third liquid-phase passage 63. Further, in the third embodiment, the second liquid-phase passage 62 and the third liquid-phase passage 63 have a relation of Va<Vb, so the liquid-phase refrigerant flowing in the second liquid-phase passage 62 is also suppressed from flowing backward to the first liquid-phase passage 61 near the collection portion 64 and hence smoothly flows to the third liquid-phase passage 63. In other words, a flowing force caused by the own weight of the liquid-phase refrigerant flowing in the second liquid-phase passage 62 is suppressed from being dispersed. Thus, the device temperature regulator 1 can increase a flow rate of the liquid-phase refrigerant to be fed to the evaporator 3 and hence can smoothly circulate the liquid-phase refrigerant in the device temperature regulator 1.

Here, in the third embodiment, the second outlet portion 426 included by the second condenser 42 is arranged on the upper side in the gravitational direction than the first outlet portion 416 included by the first condenser 41. In contrast to this, although not shown in the figure, in a case where the first outlet portion 416 included by the first condenser 41 is arranged on the upper side in the gravitational direction than the second outlet portion 426 included by the second condenser 42, the length of the first liquid-phase passage 61 corresponds to La and the volume of the first liquid-phase passage 61 corresponds to Va. In this case, the first liquid-phase passage 61 and the third liquid-phase passage 63 have relations of La<Lb and Va<Lb, as described above. In this case, the liquid-phase refrigerant flowing in the first liquid-phase passage 61 is suppressed from flowing backward to the second liquid-phase passage 62 near the collection portion 64 and hence smoothly flows to the third liquid-phase passage 63. In other words, a flowing force caused by the own weight of the liquid-phase refrigerant flowing in the first liquid-phase passage 61 is suppressed from being dispersed. Thus, the device temperature regulator 1 can increase a flow rate of the liquid-phase refrigerant to be fed to the evaporator 3 and hence can smoothly circulate the liquid-phase refrigerant in the device temperature regulator 1.

### FIRST REFERENCE EXAMPLE

A first reference example will be described. The first reference example has the first to third liquid-phase passages 61, 62, 63 changed with respect to the third embodiment.

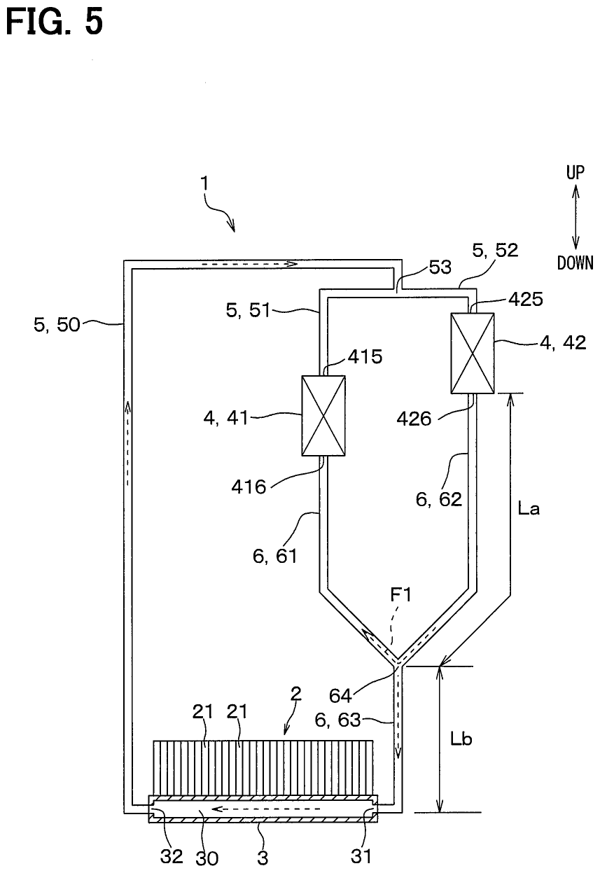

As shown in FIG. 5, also in the first reference example, as is the case with the third embodiment described above, the second outlet portion 426 included by the second condenser 42 is arranged on the upper side in the gravitational direction than the first outlet portion 416 included by the first condenser 41. In other words, a position in which the second liquid-phase passage 62 is connected to the second outlet portion 426 of the second condenser 42 is higher in the gravitational direction than a position in which first liquid-phase passage 61 is connected to the first outlet portion 416 of the first condenser 41. Also in the first reference example, of the first liquid-phase passage 61 and the second liquid-phase passage 62, a length of the liquid-phase passage which is higher between a position in which the first liquid-phase passage 61 is connected to the first condenser 41 and a position in which the second liquid-phase passage 62 is connected to the second condenser 42 will be denoted by La. A length of the third liquid-phase passage 63 will be denoted by Lb. Further, of the first liquid-phase passage 61 and the second liquid-phase passage 62, a volume of the liquid-phase passage which is higher between the position in which the first liquid-phase passage 61 is connected to the first condenser 41 and the position in which the second liquid-phase passage 62 is connected to the second condenser 42 will be denoted by Va. A volume of the third liquid-phase passage 63 will be denoted by Vb. Here, inside diameters of the first to third liquid-phase passages 61, 62, 63 are nearly equal. Also in the first reference example, a length of the second liquid-phase passage 62 which is higher in the position in which the second liquid-phase passage 62 is connected to the second condenser 42 corresponds to La, and a volume of the second liquid-phase passage 62 corresponds to Va.

However, in the first reference example, a relation between the length La of the second liquid-phase passage 62 and the length Lb of the third liquid-phase passage 63 is La>Lb. Further, a relation between the volume Va of the second liquid-phase passage 62 and the volume Vb of the third liquid-phase passage 63 is Va>Vb. In this way, in a case where the second liquid-phase passage 62 and the third liquid-phase passage 63 has the relation of La>Lb or the relation of Va>Vb, when the liquid-phase refrigerant flowing in the second liquid-phase passage 62 cannot flow into the third liquid-phase passage 63, as shown by an arrow F1 of a broken line, it can be thought that the liquid-phase refrigerant flowing in the second liquid-phase passage 62 flows backward to the first liquid-phase passage 61. The liquid-phase refrigerant flowing backward to the first liquid-phase passage 61 has its flow direction directed to the first condenser 41 and hence does not cause a force to push the liquid-phase refrigerant to the evaporator 3. Thus, in the device temperature regulator 1, a flowing force caused by the own weight of the liquid-phase refrigerant flowing in the second liquid-phase passage 62 is dispersed, and hence it is concerned that the flow rate of the liquid-phase refrigerant to be fed to the evaporator 3 is decreased.

Also in the first reference example, as is the case with the first embodiment, the first condenser 41 and the second condenser 42 are connected to each other in parallel by the gas-phase passage 5 and by the liquid-phase passage 6. In this way, the first reference example can also produce the same operations and effects as the first embodiment.

### Fourth Embodiment

A fourth embodiment will be described. The fourth embodiment has an arrangement of two condensers 41, 42 and a configuration of the medium located on the outside of each of the two condensers 41, 42 changed with respect to the first embodiment.

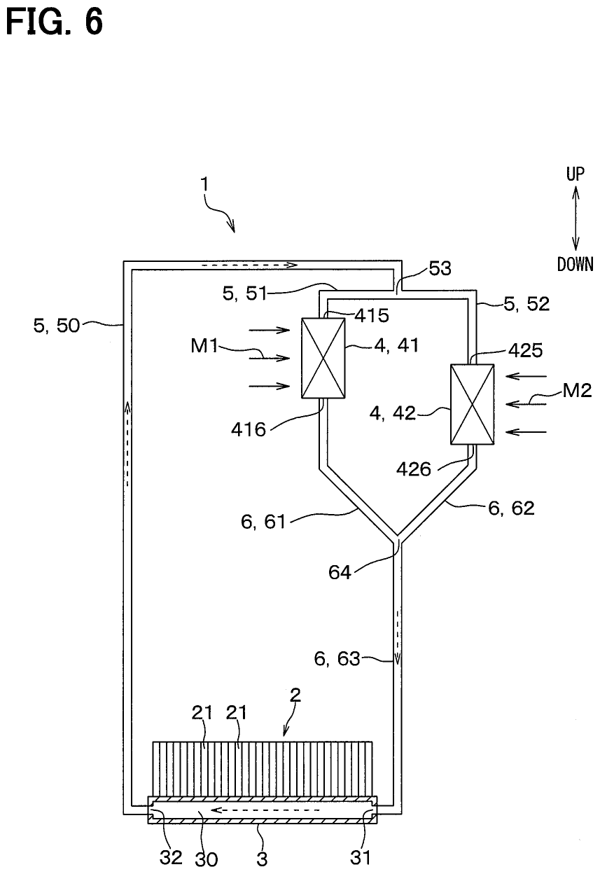

As shown in FIG. 6, in the fourth embodiment, the first outlet portion 416 included by the first condenser 41 is arranged on an upper side in the gravitational direction than the second outlet portion 426 included by the second condenser 42. In other words, a position in which the first liquid-phase passage 61 is connected to the first outlet portion 416 of the first condenser 41 is higher in the gravitational direction than a position in which the second liquid-phase passage 62 is connected to the second outlet portion 426 of the second condenser 42.

In FIG. 6, the first medium located on the outside of the first condenser 41 will be denoted by arrows M1, whereas the second medium located on the outside of the second condenser 42 will be denoted by arrows M2. The first medium and the second medium can have their temperatures set individually. In other words, in the first medium and the second medium, a temperature of one medium and a temperature of the other medium do not affect each other, and the first medium and the second medium are thermally independent of each other.

Here, of the first medium and the second medium, a temperature of the medium located on the outside of the condenser arranged at a lower position in the gravitational direction will be denoted by Ta and a temperature of the medium located on the outside of the condenser arranged at a higher position in the gravitational direction will be denoted by Tb. In the fourth embodiment, the second condenser 42 is provided at the lower position in the gravitational direction than the first condenser 41, so a temperature of the second medium located on the outside of the second condenser 42 corresponds to Ta and a temperature of the first medium located on the outside of the first condenser 41 corresponds to Tb. At this time, a relation between the temperature Ta of the second medium and the temperature Tb of the first medium is Ta<Tb. In other words, Ta is a lower temperature than Tb.

In the fourth embodiment, of the first medium and the second medium, the second medium whose temperature is lower corresponds to the second condenser 42. In this way, the amount of liquid-phase refrigerant generated in the second condenser 42 becomes more than the amount of liquid-phase refrigerant generated in the first condenser 41. On the other hand, the first outlet portion 416 included by the first condenser 41 is at a higher position in the gravitational direction than the second outlet portion 426 included by the second condenser 42. For this reason, even in a case where the liquid-phase refrigerant flowing in the second liquid-phase passage 62 passes through the collection portion 64 and flows backward to the first liquid-phase passage 61, the liquid-phase refrigerant is suppressed from flowing into the first condenser 41. Thus, the liquid-phase refrigerant condensed in the second condenser 42, in which the temperature of the medium located outside is lower, of the first condenser 41 or the second condenser 42 can be suppressed from flowing into and being again heated by the first condenser 41 in which the temperature of the medium is higher.

In this regard, in the fourth embodiment, the first outlet portion 416 included by the first condenser 41 is arranged on the upper side in the gravitational direction than the second outlet portion 426 included by the second condenser 42. In contrast to this, although not shown in the figure, in a case where the first outlet portion 416 included by the first condenser 41 is arranged on a lower side in the gravitational direction than the second outlet portion 426 of the second condenser 42, the temperature of the first medium located on the outside of the first condenser 41 corresponds to Ta and the temperature of the second medium located on the outside of the second condenser 42 corresponds to Tb. Also in this case, a relation between the temperature Ta of the first medium and the temperature Tb of the second medium is Ta<Tb.

In this case, of the first medium and the second medium, the first medium having a lower temperature is a medium corresponding to the first condenser 41. In this way, the amount of liquid-phase refrigerant generated in the first condenser 41 becomes more than the amount of liquid-phase refrigerant generated in the second condenser 42. On the other hand, in this case, the second outlet portion 426 included by the second condenser 42 is at an upper position in the gravitational direction than the first outlet portion 416 included by the first condenser 41. For this reason, even in a case where the liquid-phase refrigerant flowing in the first liquid-phase passage 61 passes through the collection portion 64 and flows backward to the second liquid-phase passage 62, the liquid-phase refrigerant is suppressed from flowing into the second condenser 42. Thus, the liquid-phase refrigerant condensed in the first condenser 41 in which the temperature of the medium located outside is lower of the first condenser 41 and the second condenser 42 can be suppressed from flowing into and being again heated by the second condenser 42 in which the temperature of the medium is higher.

### SECOND REFERENCE EXAMPLE

A second reference example will be described. The second reference example has an arrangement of two condensers 41, 42 and a configuration of the medium located on the outside of each of the two condensers 41, 42 changed with respect to the fourth embodiment.

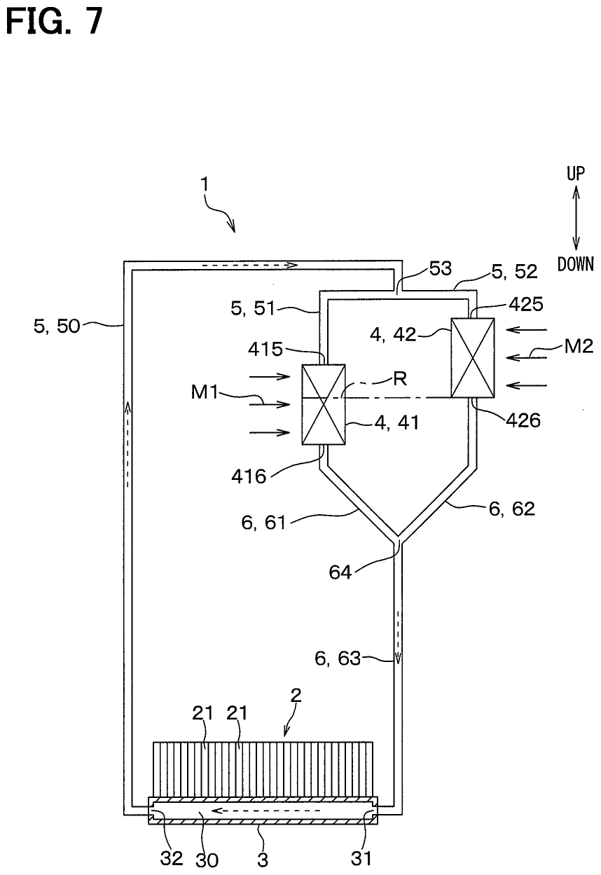

As shown in FIG. 7, in the second reference example, the first outlet portion 416 included by the first condenser 41 is arranged on a lower side in the gravitational direction than the second outlet portion 426 included by the second condenser 42. In other words, a position in which the first liquid-phase passage 61 is connected to the first outlet portion 416 of the first condenser 41 is lower in the gravitational direction than a position in which the second liquid-phase passage 62 is connected to the second outlet portion 426 of the second condenser 42.

Also in FIG. 7, the first medium located on the outside of the first condenser 41 will be denoted by an arrow M1, whereas the second medium located on the outside of the second condenser 42 will be denoted by an arrow M2. In the first medium and the second medium, a temperature of one medium and a temperature of the other medium can be set individually.

Also in the second reference example, of the first medium and the second medium, a temperature of the medium located on the outside of the condenser arranged at a lower position in the gravitational direction will be denoted by Ta and a temperature of the medium located on the outside of the condenser arranged at a higher position in the gravitational direction will be denoted by Tb. In the second reference example, the temperature of the first medium located on the outside of the first condenser 41 corresponds to Ta and the temperature of the medium located on the outside of the second condenser 42 corresponds to Tb. However, in the second reference example, a relation between the temperature Ta of the first medium and the temperature Tb of the second medium is assumed to be Ta>Tb. In other words, the second reference example is different from the fourth embodiment and Ta is a higher temperature than Tb.

In the second reference example, of the first medium and the second medium, the second medium whose temperature is lower corresponds to the second condenser 42. For this reason, the amount of liquid-phase refrigerant generated in the second condenser 42 becomes more than the amount of liquid-phase refrigerant generated in the first condenser 41. On the other hand, the first outlet portion 416 included by the first condenser 41 is at the lower position in the gravitational direction than the second outlet portion 426 included by the second condenser 42. For this reason, in a case where the liquid-phase refrigerant flowing in the second liquid-phase passage 62 passes through the collection portion 64 and flows backward to the first liquid-phase passage 61, the liquid-phase refrigerant is liable to flow into the first condenser 41. In other words, the liquid-phase refrigerant generated in the second condenser 42 is liable to flow into the first condenser 41 to a position shown by a single dot and dash line in FIG. 7. Thus, of the first condenser 41 and the second condenser 42, the liquid-phase refrigerant condensed in the second condenser 42 in which the temperature of the medium located outside is lower is liable to flow into and to be again heated by the first condenser 41 in which the temperature of the medium located outside is higher.

Also in the first reference example, as is the case with the first embodiment, the first condenser 41 and the second condenser 42 are connected to each other in parallel by the gas-phase passage 5 and by the liquid-phase passage 6. In this way, the first reference example also can produce the same operations and effects as the first embodiment.

### Fifth Embodiment

A fifth embodiment will be described. In a plurality of embodiments described below, the first medium located on the outside of the first condenser 41 and the second medium located on the outside of the second condenser 42 will be described with respect to the first embodiment to the fourth embodiment described above. In the respective figures referred to in the plurality of embodiments described below, the configuration of the evaporator 3 and its surroundings will be omitted in the figures.

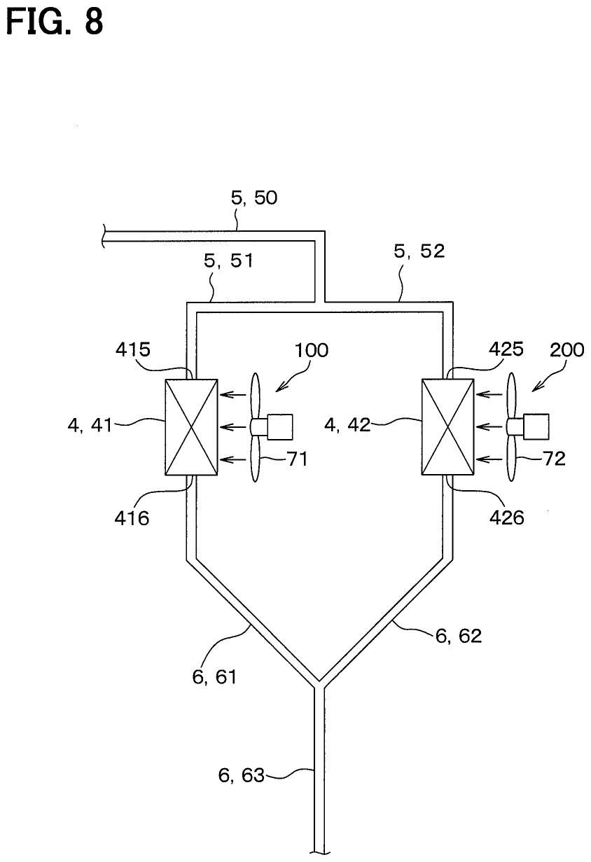

As shown in FIG. 8, a device temperature regulator 1 of the fifth embodiment is provided with a first blower 71 as an example of a first medium feed device 100 and with a second blower 72 as an example of a second medium feed device 200. The first blower 71 feeds the first condenser 41 with air as the first medium and the second blower 72 feeds the second condenser 42 with air as the second medium.

The first blower 71 feeds the first condenser 41 with air outside a vehicle compartment as the first medium at least in the summer. The air outside the vehicle compartment flows outside the first condenser 41 and exchanges heat with the refrigerant flowing in the first condenser 41. On the other hand, the second blower 72 feeds the second condenser 42 with air inside the vehicle compartment as the second medium at least in the summer. The air inside the vehicle compartment flows outside the second condenser 42 and exchanges heat with the refrigerant flowing in the second condenser 42. In general, when the vehicle travels at least in the summer, the air inside the vehicle compartment is set to a lower temperature than the air outside the vehicle compartment by an air conditioner. For this reason, the air inside the vehicle compartment as the second medium is lower in the temperature than the air outside the vehicle compartment as the first medium.

In the fifth embodiment, the temperature of the first medium and the temperature of the second medium are individually set. For this reason, the amount of liquid-phase refrigerant generated by the first condenser 41 and the amount of liquid-phase refrigerant generated by the second condenser 42 can be individually regulated to accelerate the generation of the liquid-phase refrigerant. Thus, in the fifth embodiment, when a condensing capacity of the refrigerant by one condenser of the first condenser 41 and the second condenser 42 is low, by increasing the condensing capacity of the refrigerant by the other condenser, the evaporator 3 can be fed with the liquid-phase refrigerant.

Further, in the fifth embodiment, when the amount of heat generated by the battery 2 is large, the device temperature regulator 1 can use the medium of a lower temperature of the first medium and the second medium to increase the amount of liquid-phase refrigerant to be generated and can sufficiently cool the battery 2. On the other hand, when the amount of heat generated by the battery 2 is small, the device temperature regulator 1 can use the medium of a higher temperature of the first medium and the second medium to cool the battery 2 to a suitable temperature. Thus, the device temperature regulator 1 can perform a temperature regulation according to the amount of heat generated by the battery 2.

### Sixth Embodiment

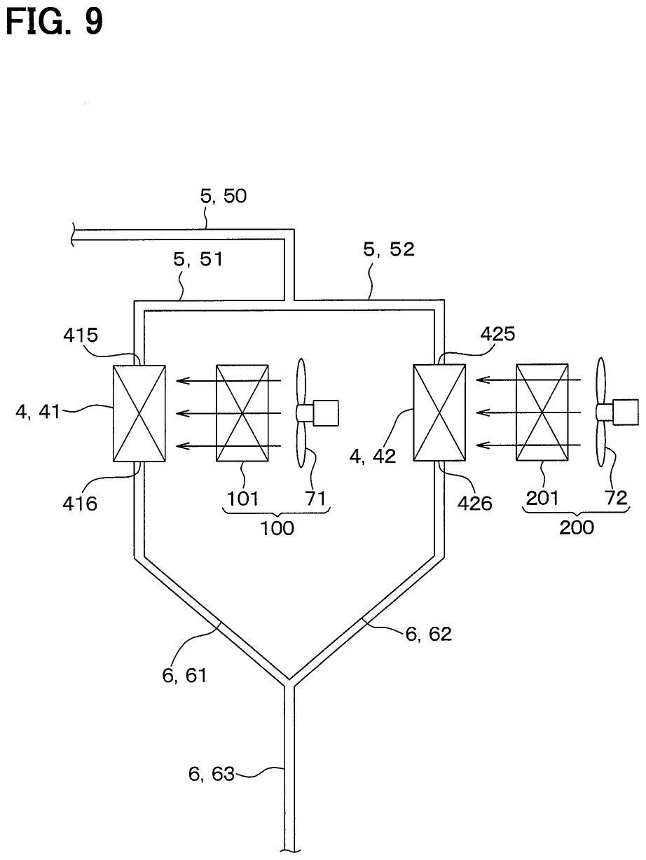

A sixth embodiment will be described. As shown in FIG. 9, a device temperature regulator 1 of the sixth embodiment is provided with the first blower 71 and a first cold heat feed device 101 as an example of a first medium feed device 100. Further, the device temperature regulator 1 of the sixth embodiment is provided with a second blower 72 and a second cold heat feed device 201 as an example of a second medium feed device 200. Each of the first cold heat feed device 101 and the second cold heat feed device 201 is configured of, for example, a low-pressure side heat exchanger configuring a refrigeration cycle or a heat exchanger configuring a circulation cycle of a cooling water, or the like.

The first medium feed device 100 generates an air flow by the first blower 71 to thereby feed the first condenser 41 with air passing through the first cold heat feed device 101 as the first medium. In this way, the refrigerant flowing in the first condenser 41 is cooled. The first medium feed device 100 can regulate the temperature of the first cold heat feed device 101 to thereby regulate the temperature of the air as the first medium.

The second medium feed device 200 generates an air flow by the second blower 72 to thereby feed the second condenser 42 with air passing through the second cold heat feed device 201 as the second medium. In this way, the refrigerant flowing in the second condenser 42 is cooled. The second medium feed device 200 also can regulate the temperature of the second cold heat feed device 201 to thereby regulate the temperature of the air as the second medium.

Also in the sixth embodiment, the temperature of the first medium and the temperature of the second medium can be individually set. For this reason, even when a condensing capacity of the refrigerant by one condenser of the first condenser 41 and the second condenser 42 is low, by increasing the condensing capacity of the medium by the other condenser, the evaporator 3 can be fed with the liquid-phase refrigerant.

### Seventh Embodiment

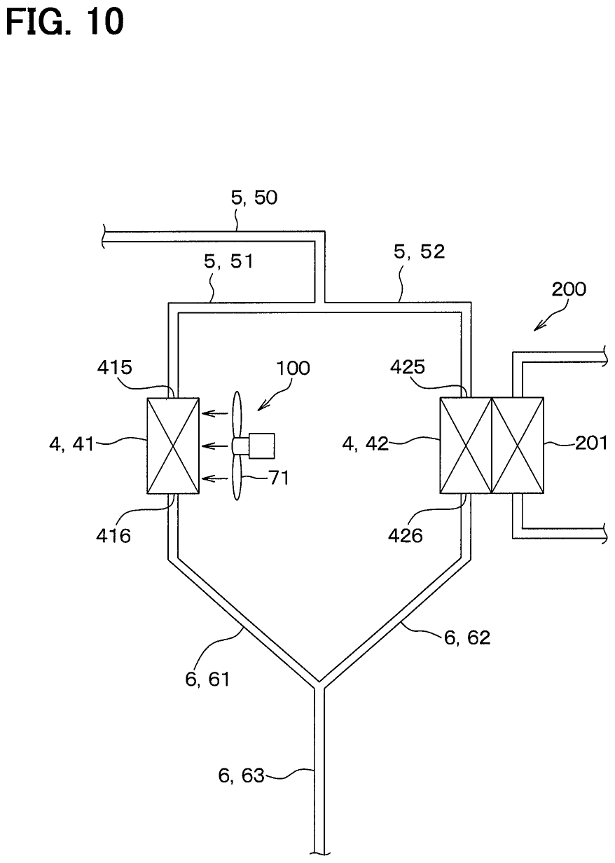

A seventh embodiment will be described. As shown in FIG. 10, a device temperature regulator 1 of the seventh embodiment is provided with the first blower 71 as an example of the first medium feed device 100. The first blower 71 feeds the first condenser 41 with air as the first medium. The air flows outside the first condenser 41 and exchanges heat with the refrigerant flowing in the first condenser 41.

Further, the device temperature regulator 1 is provided with the second cold heat feed device 201 as an example of the second medium feed device 200. The second cold heat feed device 201 is configured of, for example, a low-pressure side heat exchanger configuring a refrigeration cycle or a heat exchanger configuring a circulation cycle of a cooling water, or the like. In a case where the second cold heat feed device 201 is the low-pressure side heat exchanger configuring the refrigeration cycle, the second cold heat feed device 201 feeds the second condenser 42 with a cold heat of the refrigerant circulating in the refrigeration cycle as the second medium. On the other hand, in a case where the second cold heat feed device 201 is the heat exchanger configuring the circulation cycle of the cooling water, the second cold heat feed device 201 feeds the second condense 42 with the cold heat of the cooling water as the second medium. The refrigerant flowing in the second condenser 42 is cooled by heat conduction from the refrigerant or the cooling water as the second medium. The second cold heat feed device 201 can regulate an output of the refrigeration cycle or the circulation cycle of the cooling water to thereby regulate a cold heat amount to be fed to the refrigerant flowing in the second condenser 42.

In the seventh embodiment, the first medium feed device 100 is the first blower 71. The second medium feed device 200 is the low-pressure side heat exchanger configuring the refrigeration cycle or the heat exchanger configuring the circulation cycle of the cooling water.

According to this, for example, when the amount of heat generated by the battery 2, for example, when the vehicle travels in a city, by using the blower as the first medium feed device 100, a power consumption necessary for cooling the battery 2 can be reduced as compared with a case where the refrigeration cycle is driven.

On the other hand, the second medium feed device 200 can set the temperature of the refrigerant of the refrigeration cycle or the cooling water as the second medium to a temperature lower than the temperature of the air as the first medium. For example, when the amount of heat generated by the battery 2 is large, for example, when the vehicle travels at high speeds, by using the refrigeration cycle as the second medium feed device 200, the battery 2 can be sufficiently cooled. Thus, the device temperature regulator 1 can reduce a power consumption necessary for cooling the battery 2 and can perform a temperature regulation according to the amount of heat generated by the battery 2.

Further, in the seventh embodiment, the first medium and the second medium are different kinds of media. According to this, the first medium and the second medium can be easily set to different temperatures. For this reason, when the amount of heat generated by the battery 2 is small, for example, when the vehicle travels in the city, the air whose temperature is comparatively higher than the second medium can be used as the first medium to cool the battery 2 to a suitable temperature. On the other hand, when the amount of heat generated by the battery 2 is large, for example, when the vehicle travels at high speeds, the refrigerant or the cooling water whose temperature is low can be used as the second medium to sufficiently cool the battery 2. Hence, the device temperature regulator 1 can perform the temperature regulation according to the amount of heat generated by the battery 2.

### Eighth Embodiment

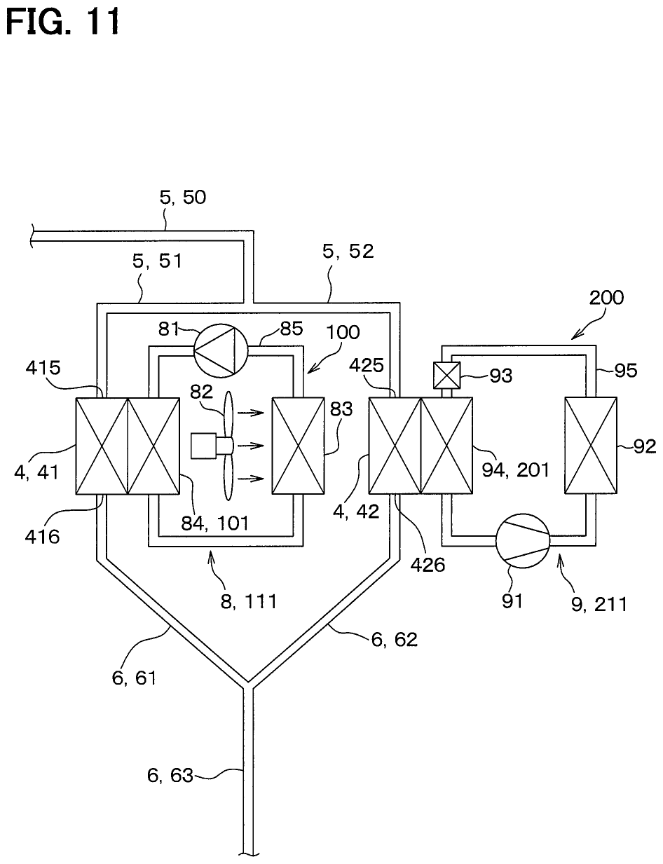

An eighth embodiment will be described. As shown in FIG. 11, a device temperature regulator 1 of the eighth embodiment is provided with a circulation cycle 8 of a cooling water as an example of the first medium feed device 100. Specifically, the circulation cycle 8 of the cooling water configures a first medium circulation circuit 111 which has a pump 81, a blower 82, an air-cooled radiator 83, and a heat exchanger 84 annularly connected to each by a pipe 85 and in which the cooling water is circulated.

The pump 81 circulates the cooling water in the pipe 85. The blower 82 blows air to the air-cooled radiator 83. In this way, the cooling water flowing in the air-cooled radiator 83 is cooled. The heat exchanger 84 corresponds to the first cold heat feed device 101. The cooling water flowing in the heat exchanger 84 exchanges heat with the refrigerant flowing in the first condenser 41 to cool the refrigerant flowing in the first condenser 41. The cooling water absorbing heat in the heat exchanger 84 flows to the air-cooled radiator 83.

Further, the device temperature regulator 1 is provided with a refrigeration cycle 9 as an example of the second medium feed device 200. Specifically, the refrigeration cycle 9 configures a second medium circulation circuit 211 which has a compressor 91, a high-pressure side heat exchanger 92, an expansion valve 93, and a low-pressure side heat exchanger 94 annularly connected to each other by a pipe 95 and in which the refrigerant is circulated. The first medium circulation circuit 111 and the second medium circulation circuit 211 are independent from each other.

The refrigerant used in the refrigeration cycle 9 may be the same as or different from the refrigerant as a working fluid used in the device temperature regulator 1.

The compressor 91 sucks the refrigerant from the low-pressure side heat exchanger 94 and compresses the refrigerant. The compressor 91 has power transmitted from an engine for running the vehicle or an electric motor (not shown in the figure), thereby being driven.

The high-pressure gas-phase refrigerant discharged from the compressor 91 flows into the high-pressure side heat exchanger 92. When the high-pressure gas-phase refrigerant flowing into the high-pressure side heat exchanger 92 flows in a channel of the high-pressure side heat exchanger 92, the high-pressure gas-phase refrigerant exchanges heat with the outside air blown from the blower (not shown in the figure), thereby being cooled and condensed.

When a liquid-phase refrigerant condensed in the high-pressure side heat exchanger 92 passes through the expansion valve 93, the liquid-phase refrigerant is condensed and is brought into a misty gas-liquid two-phase state and then flows into the low-pressure side heat exchanger 94. The expansion valve 93 is configured of a fixed throttle like a nozzle or a suitable variable throttle. The low-pressure side heat exchanger 94 corresponds to the second cold heat feed device 201. The low-pressure side heat exchanger 94 cools the refrigerant flowing in the second condenser 42 by a heat of evaporation of the refrigerant flowing in itself. The refrigerant passing through the low-pressure side heat exchanger 94 is sucked by the compressor 91 via an accumulator (not shown in the figure).

In the eighth embodiment, the first medium circulation circuit 111 in which the cooling water as the first medium is circulated and the second medium circulation circuit 211 in which the refrigerant as the second medium is circulated are independent from each other. According to this, the temperature of the first medium and the temperature of the second medium are individually set, which hence can prevent the temperature of the first medium and the temperature of the second medium from affecting each other. Hence, in the eighth embodiment, when the condensing capacity of the refrigerant by one condenser of the first condenser 41 and the second condenser 42 is low, by increasing the condensing capacity of the refrigerant by the other condenser, the evaporator 3 can be fed with the liquid-phase refrigerant.

In the eighth embodiment, the device temperature regulator 1 employs the low-pressure side heat exchanger 94 configuring the refrigeration cycle 9 as an example of the second medium feed device 200. According to this, in a case where the device temperature regulator 1 is mounted on a vehicle, the low-pressure side heat exchanger 94 of the refrigeration cycle of an air conditioner mounted on the vehicle can be used as a medium feed device, and thereby the configuration of the device temperature regulator 1 can be made simple.

Further, in the eighth embodiment, the cooling water as the first medium and the refrigerant of the refrigeration cycle as the second medium are different kinds of media. According to this, the temperature of the first medium and the temperature of the second medium can be easily set to different temperatures. Thus, the device temperature regulator 1 can perform a temperature regulation according to the amount of heat generated by the battery 2.

### Ninth Embodiment

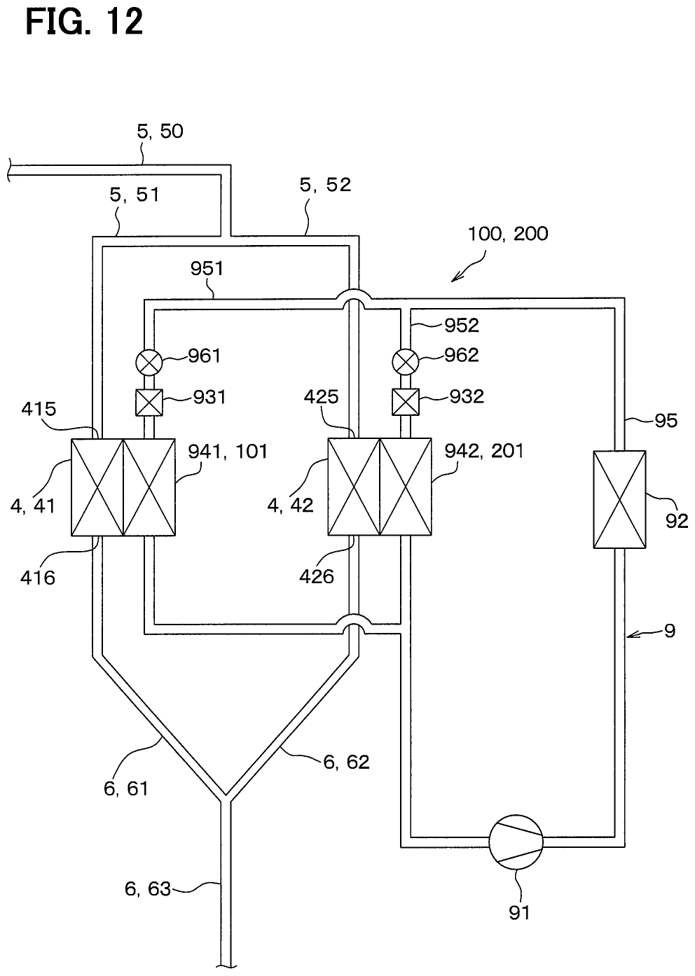

A ninth embodiment will be described. As shown in FIG. 12, in the ninth embodiment, each of the first medium feed device 100 and the second medium feed device 200 included by the device temperature regulator 1 is configured of the same refrigeration cycle 9. In this refrigeration cycle 9, a first low-pressure side heat exchanger 941 corresponding to the first cold heat feed device 101 and a second low-pressure side heat exchanger 942 corresponding to the second cold heat feed device 201 are connected to each other in parallel.

Specifically, the refrigeration cycle 9 configures a circulation circuit which has a compressor 91, a high-pressure side heat exchanger 92, a first flow rate regulation valve 961, a first expansion valve 931, a first low-pressure side heat exchanger 941, a second flow rate regulation valve 962, a second expansion valve 932, and a second low-pressure side heat exchanger 942 annularly connected to each other by a pipe 95 and in which the refrigerant is circulated.

The compressor 91 and the high-pressure side heat exchanger 92 are substantially the same as those described in the eighth embodiment.

The liquid-phase refrigerant condensed in the high-pressure side heat exchanger 92 flows separately to the first low-pressure side heat exchanger 941 and the second low-pressure side heat exchanger 942 via branched pipes 951, 952. The pipe 951 on the first low-pressure side heat exchanger 941 is provided with the first flow rate regulation valve 961 for regulating a flow rate of the refrigerant. The liquid-phase refrigerant passing through the first flow rate regulation valve 961 has its pressure reduced when passing through the first expansion valve 931, thereby being brought into a misty gas-liquid two-phase state and flowing into the first low-pressure side heat exchanger 941. The first low-pressure side heat exchanger 941 corresponds to the first cold heat feed device 101.

The first low-pressure side heat exchanger 941 is provided so as to be able to exchange heat with the refrigerant flowing in the first condenser 41 of the device temperature regulator 1. The refrigerant flowing in a channel of the first low-pressure side heat exchanger 941 absorbs heat from the refrigerant flowing in the first condenser 41 of the device temperature regulator 1, thereby being evaporated. The low-pressure refrigerant flowing in the first condenser 41 of the device temperature regulator 1 is cooled and condensed by a latent heat of evaporation of the low-pressure refrigerant flowing in the channel of the first low-pressure side heat exchanger 941. The refrigerant passing through the first low-pressure side heat exchanger 941 is sucked by the compressor 91 via an accumulator (not shown in the figure).

On the other hand, the pipe 952 on the second low-pressure side heat exchanger 942 is also provided with the second flow rate regulation valve 962 for regulating a flow rate of the refrigerant. The liquid-phase refrigerant passing through the second flow rate regulation valve 962 has its pressure reduced when passing through the second expansion valve 932, thereby being brought into a misty gas-liquid two-phase state and flowing into the second low-pressure side heat exchanger 942. The second low-pressure side heat exchanger 942 corresponds to the second cold heat feed device 201. The second low-pressure side heat exchanger 942 is provided so as to able to exchange heat with the refrigerant flowing in the second condenser 42 of the device temperature regulator 1. The low-pressure refrigerant flowing in the channel of the second low-pressure side heat exchanger 942 absorbs heat from the refrigerant flowing in the second condenser 42 of the device temperature regulator 1, thereby being evaporated. The refrigerant flowing in the second condenser 42 of the device temperature regulator 1 is cooled and condensed by a latent heat of evaporation of the low-pressure refrigerant flowing in the channel of the second low-pressure side heat exchanger 942. The refrigerant passing through the second low-pressure side heat exchanger 942 is also sucked by the compressor 91 via an accumulator (not shown in the figure).

In the ninth embodiment, a cold heat amount to be fed to the refrigerant flowing in the first condenser 41 and a cold heat amount to be fed to the refrigerant flowing in the second condenser 42 can be regulated by the first flow rate regulation valve 961 and the second flow rate regulation valve 962 which are included by the refrigeration cycle 9. A flow rate regulation by the first flow rate regulation valve 961 and a flow rate regulation by the second flow rate regulation valve 962 are performed by regulating an on-off time of the first flow rate regulation valve 961 and the second flow rate regulation valve 962 respectively. By regulating an output of the refrigeration cycle 9 in this way, when the condensing capacity of the refrigerant by one condenser of the first condenser 41 and the second condenser 42 is low, by increasing the condensing capacity of the refrigerant of the other condenser, the evaporator 3 can be fed with the liquid-phase refrigerant. Thus, the ninth embodiment can also produce the same operations and effects as the fifth embodiment to the eighth embodiment.

Further, in the ninth embodiment, by using the first low-pressure side heat exchanger 941 and the second low-pressure side heat exchanger 942, which configure the refrigeration cycle 9, respectively as the first cold heat feed device 101 and the second cold heat feed device 201, a refrigerant condensing capacity of each of the first condenser 41 and the second condenser 42 can be enhanced. Further, by using the first low-pressure side heat exchanger 941 and the second low-pressure side heat exchanger 942 of the refrigeration cycle 9 of the air conditioner mounted in the vehicle respectively as the first cold heat feed device 101 and the second cold heat feed device 201, the configuration of the device temperature regulator 1 can be made simple.

### Tenth Embodiment

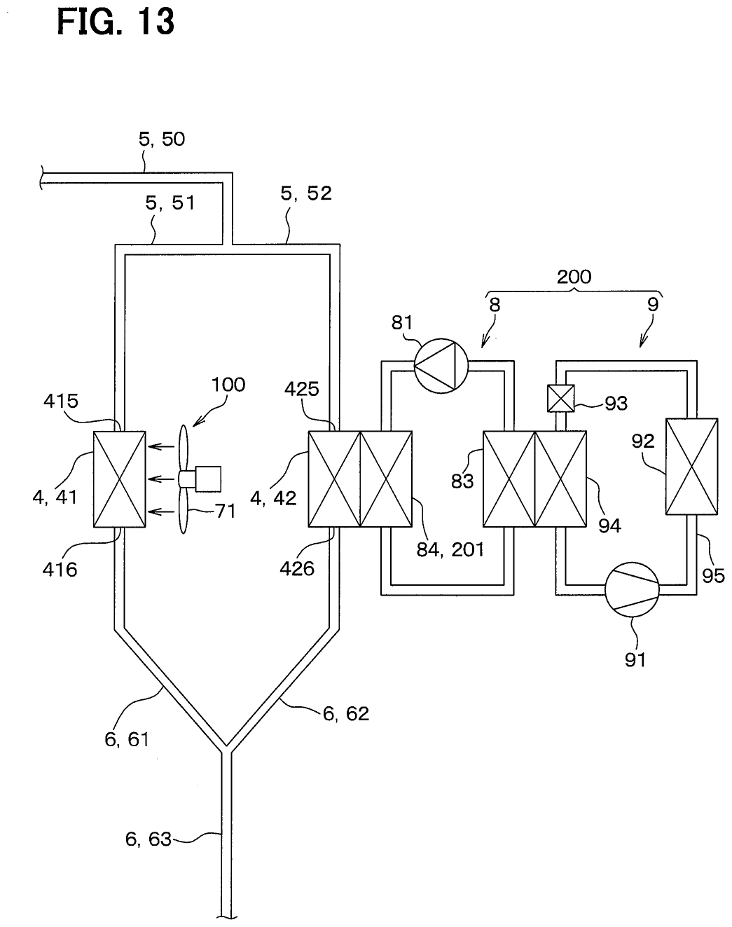

A tenth embodiment will be described. As shown in FIG. 13, the tenth embodiment is a modification of the seventh embodiment.

A device temperature regulator 1 of the tenth embodiment is provided with the first blower 71 as an example of the first medium feed device 100. Further, the device temperature regulator 1 is provided with the so-called secondary loop configuration including the circulation cycle 8 of the cooling water and the refrigeration cycle 9. The heat exchanger 84 configuring the circulation cycle 8 of the cooling water corresponds to the second cold heat feed device 201.

The circulation cycle 8 of the cooling water has a pump 81, a heat exchanger 84, and a radiator 83 annularly connected to each other by a pipe 85. The radiator 83 of the circulation cycle 8 of the cooling water is configured so as to be able to exchange heat with the low-pressure side heat exchanger 94 configuring the refrigeration cycle 9. The compressor 91, the high-pressure side heat exchanger 92, the expansion valve 93, and the low-pressure side heat exchanger 94 which configure the refrigeration cycle 9 are substantially the same as those described in the eighth embodiment.

In the tenth embodiment, the cooling water flowing in the second cold heat feed device 201 is cooled by the low-pressure side heat exchanger 94 configuring the refrigeration cycle 9. The second cold heat feed device 201 can regulate a cold heat amount to be fed to the refrigerant flowing in the second condenser 42 from the second cold heat feed device 201 by regulating an output of the refrigeration cycle 9. The tenth embodiment can also produce the same operations and effects as the seventh embodiment.

### Other Embodiments

The present disclosure is not limited to the embodiments described above but can be changed as appropriate. Further, the respective embodiments described above are not unrelated to each other but can be combined with each other as appropriate except where the combination of the embodiments is clearly impossible. Still further, it is needless to say that in each of the embodiments, elements configuring the embodiment are not necessarily essential except where it is specified that the elements are especially essential or except where the elements are thought to be essential in principle. Still further, in each of the embodiments described above, in a case where numerical values of a number, a numerical value, an amount, a range, and the like of the constituent element of the embodiment are referred to, it is not limited to the special numerical values except where it is specified that the numerical values are especially essential and except where the numerical values are limited to the special numerical values in principle. Still further, in each of the embodiments, when a shape or a position relation of the constituent element is referred to, the shape or the position relation of the constituent element is not limited to the shape or the position relation which are referred to except where the shape or the position relation is especially specified or except where the shape or the position relation is limited to a specific shape or a specific position relation in principle.

For example, in the embodiments described above, the device temperature regulator 1 cools the battery 2 of the vehicle, but in the other embodiment, the target device to be cooled by the device temperature regulator 1 may be various kinds of devices included by the vehicle.

For example, in the embodiments described above, the device temperature regulator 1 cools the battery 2, but in the other embodiment, the device temperature regulator 1 may heat the battery 2. In this case, the evaporator 3 condenses the refrigerant and condenser 4 evaporates the refrigerant.

For example, in the embodiments described above, the evaporator 3 is configured of a case formed in a flat shape, but in the other embodiment, the evaporator 3 may be configured so as to include a heat exchange tube.

For example, in the embodiments described above, the device temperature regulator 1 is provided with two condensers, but in the other embodiment, the device temperature regulator 1 may be provided with three or more condensers.

For example, in the embodiments described above, the first medium feed device 100 or the second medium feed device 200 is exemplified by the circulation cycle 8 of the cooling water, the refrigeration cycle 9, or the blowers 71, 72, but is not limited to these. In the other embodiments, various kinds of materials such as a thermo-module provided with a Peltier element or a cooling body generating a refrigerating operation by a magnetism may be applied to the first medium feed device 100 or the second medium feed device 200.

For example, in the embodiments described above, the liquid-phase passage 6 includes the first liquid-phase passage 61, the second liquid-phase passage 62, the collection portion 64, and the third liquid-phase passage. In contrast to this, in the other embodiment, the liquid-phase passage 6 may include at least the first liquid-phase passage 61 and the second liquid-phase passage 62. In this case, each of the first liquid-phase passage 61 and the second liquid-phase passage 62 is configured so as to be individually connected to the evaporator 3.

### SUMMARY

According to a first aspect described in a part or all of the embodiments described above, the device temperature regulator regulates a temperature of a target device and includes an evaporator, a first condenser, a second condenser, a gas-phase passage, a first liquid-phase passage, a second liquid-phase passage, a collection portion, and a third liquid-phase passage. The evaporator cools the target device by the latent heat of evaporation of the working fluid which absorbs heat from the target device and which is then evaporated. The first condenser includes the first heat exchange passage which is provided on the upper side in the gravitational direction than the evaporator and which condenses the working fluid evaporated in the evaporator by the heat exchange with the first medium located outside. The second condenser includes the second heat exchange passage which is provided on the upper side in the gravitational direction than the evaporator and which condenses the working fluid evaporated in the evaporator by the heat exchange with the second medium located outside. The gas-phase passage causes the working fluid evaporated in the evaporator to flow to the first condenser and the second condenser. The first liquid-phase passage extends from the first condenser and causes the working fluid condensed in the first condenser to flow to the evaporator. The second liquid-phase passage extends from the second condenser and causes the working fluid condensed in the second condenser to flow to the evaporator.

According to a second aspect, the first medium located on the outside of the first heat exchange passage and the second medium located on the outside of the second heat exchange passage can have their temperatures set individually.

According this, it can be said that in the first medium and the second medium, the temperature of one medium and the temperature of the other medium do not have an effect on each other, that is, the first medium and the second medium are thermally independent from each other. For this reason, for example, when the amount of heat generated by the target device is large, by using the medium whose temperature is lower of the first medium and the second medium, the production of the working fluid of the liquid phase can be increased and the target device can be sufficiently cooled. On the other hand, when the amount of heat generated by the target device is small, by using the medium whose temperature is higher of the first medium and the second medium, the target device can be cooled to a suitable temperature. Thus, the device temperature regulator can perform the temperature regulation according to the amount of heat generated by the target device.

According to a third aspect, the first condenser has the plurality of first heat exchange passages and the second condenser has the plurality of second heat exchange passages. Of the plurality of first heat exchange passages included by the first condenser and the plurality of second heat exchange passages included by the second condenser, at least one of them extend along the gravitational direction.

According to this, of the first heat exchange passages and the second heat exchange passages, the passages extending along the gravitational direction can cause the working fluid of the liquid phase to smoothly flow downward in the gravitational direction by its own weight. Thus, the device temperature regulator can smoothly circulate the working fluid and can improve the cooling capacity of the target device.

According to a fourth aspect, when the length of the liquid-phase passage, whose position connected to the condenser is higher in the gravitational direction, of the first liquid-phase passage and the second liquid-phase passage will be denoted by La and the length of the third liquid-phase passage will be denoted by Lb, the relation of La<Lb holds.

According to this, when the inner diameters of the first to the third liquid-phase passages are made nearly equal to each other, the volume of the third liquid-phase passage is larger than the volume of the liquid-phase passage, whose position connected to the condenser is higher in the gravitational direction, of the first liquid-phase passage and the second liquid-phase passage. For this reason, the working fluid flowing in the liquid-phase passage whose position is higher in the gravitational direction is suppressed from flowing backward near the collection portion and hence smoothly flows in the third liquid-phase passage. In other words, a flowing force is suppressed from being dispersed by the own weight of the working fluid flowing in the liquid-phase passage, whose position connected to the condenser is higher in the gravitational direction, of the first liquid-phase passage and the second liquid-phase passage. Thus, the device temperature regulator can increase the flow rate of the working fluid to be fed to the evaporator and can smoothly circulate the working fluid to the device temperature regulator by the own weight of the working fluid flowing in the liquid-phase passage, whose position connected to the condenser is higher in the gravitational direction, of the first liquid-phase passage and the second liquid-phase passage.

According to a fifth aspect, when the volume of the liquid-phase passage, whose position connected to the condenser is higher in the gravitational direction, of the first liquid-phase passage and the second liquid-phase passage will be denoted by Va and the volume of the third liquid-phase passage will be denoted by Vb, the relation of Va<Vb holds.

Accordingly, a flowing force is suppressed from being dispersed by the own weight of the working fluid flowing in the liquid-phase passage, whose position connected to the condenser is higher in the gravitational direction, of the first liquid-phase passage and the second liquid-phase passage. For this reason, the device temperature regulator can smoothly circulate the working fluid by the own weight of the working fluid flowing in the liquid-phase passage, whose position connected to the condenser is higher in the gravitational direction, of the first liquid-phase passage and the second liquid-phase passage.

According to a sixth aspect, when the temperature of the medium located on the outside of the condenser, whose position connected to the liquid-phase phase passage is lower in the gravitational direction, of the first condenser and the second condenser will be denoted by Ta and the temperature of the medium located on the outside of the condenser, whose position connected to the liquid-phase passage is higher in the gravitational direction, of the first condenser and the second condenser will be denoted by Tb, the relation of Ta<Tb holds.

Accordingly, of the first condenser and the second condenser, the condenser in which the temperature Tb of the medium is higher is at the higher position in the gravitational direction than the condenser in which the temperature Ta of the medium is lower. For this reason, in a case where the working fluid of the liquid phase flows backward near the collection portion, the working fluid condensed in the condenser in which the temperature of the medium is lower of the first condenser and the second condenser is suppressed from flowing into the condenser in which the temperature of the medium is higher. Thus, the working fluid condensed in the condenser in which the temperature of the medium is lower of the first condenser and the second condenser can be suppressed from flowing into and being again heated by the condenser in which the temperature of the medium is higher.

According to a seventh aspect, the first medium located on the outside of the first heat exchange passage and the second medium located on the outside of the second heat exchange passage are different kinds of media.

According to this, the first medium and the second medium can be easily set to different temperatures. For this reason, for example, when the amount of heat generated by the target device is large, by using the medium having a lower temperature of the first medium and the second medium, the production of the working fluid of the liquid phase can be increased and the target device can be sufficiently cooled. On the other hand, when the amount of heat generated by the target device is small, by using the medium having a higher temperature of the first medium and the second medium, the target device can be cooled to a suitable temperature. Thus, the device temperature regulator can perform the temperature regulation according to the amount of heat generated by the target device.

According to an eighth aspect, the device temperature regulator is further provided with the first medium feed device and the second medium feed device. The first medium feed device feeds the first condenser with the first medium. The second medium feed device feeds the second condenser with the second medium.

According to this, the amount of cold heat which is fed to the working fluid flowing in the first condenser from the first medium by the first medium feed device can be regulated and the amount of cold heat which is fed to the working fluid flowing in the second condenser from the second medium by the second medium feed device can be regulated. Thus, even when the condensing capacity of the refrigerant by one condenser of the first condenser and the second condenser is low, by increasing the condensing capacity of the refrigerant by the other condenser, the evaporator can be fed with the liquid-phase refrigerant.

According to a ninth aspect, the first medium feed device includes the first medium circulation circuit in which the first medium is circulated, and the second medium feed device includes the second medium circulation circuit in which the second medium is circulated. Here, the first medium circulation circuit and the second medium circulation circuit are independent from each other.

According to this, it is possible to prevent the temperature of the first medium and the temperature of the second medium from affecting each other. Thus, the amount of cold heat to be fed to the working fluid flowing in the first condenser from the first medium by the first medium feed device can be suitably regulated and the amount of cold heat to be fed to the working fluid flowing in the second condenser from the second medium by the second medium feed device can be suitably regulated.

According to a tenth aspect, at least one of the first medium feed device and the second medium feed device is the low-pressure side heat exchanger configuring the refrigeration cycle.

According to this, in a case where the device temperature regulator is mounted on a vehicle, by using the low-pressure side heat exchanger of the refrigeration cycle of the air conditioner mounted on the vehicle as the medium feed device, the configuration of the device temperature regulator can be made simple.

According to an eleventh aspect, of the first condenser and the second condenser, one condenser is lower in the gravitational direction in the position connected to the liquid-phase passage than the other condenser. The medium feed device which feeds the medium to the condenser, whose position connected to the liquid-phase passage is lower in the gravitational direction, of the first medium feed device and the second medium feed device can set the temperature of the medium to a lower temperature than the medium feed device which feeds the medium to the condenser, whose position connected to the liquid-phase passage is higher in the gravitational direction, of the first medium feed device and the second medium feed device.

According to this, the production of the working fluid of the liquid phase generated in the condenser, whose position connected to the liquid-phase passage is lower in the gravitational direction, of the first condenser and the second condenser becomes more than the production of the working fluid of the liquid phase generated in the condenser whose position is higher in the gravitational direction. For this reason, in a case where the working fluid of the liquid phase flows backward near the collection portion, the working fluid condensed in the condenser, whose position connected to the liquid-phase passage is lower in the gravitational direction, of the first condenser and the second condenser is suppressed from flowing into the condenser whose position is higher. Thus, the working fluid condensed in the condenser, in which the temperature of the medium located on the outside of the heat exchange passage is set to a lower temperature, of the first condenser and the second condenser can be suppressed from flowing into and being again heated by the condenser in which the temperature of the medium is set to a higher temperature.

According to a twelfth aspect, the medium feed device which feeds the medium to the condenser, whose position connected to the liquid-phase passage is lower in the gravitational direction, of the first medium feed device and the second medium feed device is the low-pressure side heat exchanger configuring the refrigeration cycle. On the other hand, the medium feed device which feeds the medium to the condenser, whose position connected to the liquid-phase passage is higher in the gravitational direction, of the first medium feed device and the second medium feed device is the blower.

According to this, for example, when the amount of heat generated by the target device is small, by using the blower as the first medium feed device, the power consumption necessary for cooling the target device can be reduced as compared with a case where the refrigeration cycle is driven.

On the other hand, the second medium feed device can set the refrigerant of the refrigeration cycle as the second medium to a temperature lower than the air as the first medium. For example, when the amount of heat generated by the target device is large, by using the low-pressure side heat exchanger configuring the refrigeration cycle of the second medium feed device, the target device can be sufficiently cooled. Hence, the device temperature regulator can reduce the power consumption necessary for cooling the target device and can perform the temperature regulation according to the amount of heat generated by the target device.

1. A device temperature regulator for regulating a temperature of a target device, comprising:
an evaporator configured to cool the target device by latent heat of evaporation of a working fluid by absorbing heat from the target device to be evaporated;
a first condenser that is provided on an upper side in a gravitational direction than the evaporator and that includes a first heat exchange passage to condense the working fluid evaporated in the evaporator by a heat exchange with a first medium outside of the first heat exchange passage;
a second condenser that is provided on an upper side in the gravitational direction than the evaporator and that includes a second heat exchange passage to condense the working fluid evaporated in the evaporator by a heat exchange with a second medium outside of the second heat exchange passage;
a gas-phase passage that causes the working fluid evaporated in the evaporator to flow to the first condenser and the second condenser;
a first liquid-phase passage that extends from the first condenser and that causes the working fluid condensed in the first condenser to flow to the evaporator; and
a second liquid-phase passage that extends from the second condenser and that causes the working fluid condensed in the second condenser to flow to the evaporator, wherein
the first medium outside of the first heat exchange passage and the second medium outside of the second heat exchange passage have respective temperatures that are capable of setting individually.

2. (canceled)

3. The device temperature regulator according to claim 1, wherein
the first condenser includes a plurality of the first heat exchange passages and the second condenser includes a plurality of the second heat exchange passages, and
at least one of the plurality of the first heat exchange passages included by the first condenser and the plurality of the second heat exchange passages included by the second condenser, extend along the gravitational direction.

4. The device temperature regulator according to claim 1, further comprising:
a collection portion in which the working fluid flowing in the first liquid-phase passage and the working fluid flowing in the second liquid-phase passage collect; and
a third liquid-phase passage that has one end connected to the collection portion and that has another end connected to the evaporator and in which the working fluid collected at the collection portion flows to the evaporator,
wherein when a length of one of the first liquid-phase passage or the second liquid-phase passage, whose position connected to the first condenser or the second condenser, is higher in the gravitational direction, is denoted by La and a length of the third liquid-phase passage is denoted by Lb, a relation of La and Lb is La<Lb.

5. The device temperature regulator according to claim 1, further comprising:
a collection portion in which the working fluid flowing in the first liquid-phase passage and the working fluid flowing in the second liquid-phase passage collects; and
a third liquid-phase passage that has one end connected to the collection portion and that has another end connected to the evaporator and in which the working fluid collected at the collection portion flows to the evaporator,
wherein when a volume of one of the first liquid-phase passage or the second liquid-phase passage, whose position connected to the first condenser or the second condenser is higher in the gravitational direction is denoted by Va and a volume of the third liquid-phase passage is denoted by Vb, a relation of Va and Vb is Va<Vb.

6. The device temperature regulator according to claim 1, wherein
when a temperature of one medium of the first medium outside of the first condenser and the second medium outside of the second condenser, whose position connected to the liquid-phase passage is lower in the gravitational direction, is denoted by Ta and a temperature of another medium of the first medium outside of the first condenser and the second medium outside of the second condenser, whose position connected to the liquid-phase passage is higher in the gravitational direction, is denoted by Tb, a relation of Ta and Tb is Ta<Tb.

7. The device temperature regulator according to claim 1, wherein
the first medium outside of the first heat exchange passage and the second medium outside of the second heat exchange passage are different kinds of media.

8. The device temperature regulator according to claim 1, further comprising:
a first medium feed device that feeds the first condenser with the first medium; and
a second medium feed device that feeds the second condenser with the second medium.

9. The device temperature regulator according to claim 8, wherein
the first medium feed device includes a first medium circulation circuit in which the first medium is circulated,
the second medium feed device includes a second medium circulation circuit in which the second medium is circulated, and
the first medium circulation circuit and the second medium circulation circuit are independent from each other.

10. The device temperature regulator according to claim 8, wherein
at least one of the first medium feed device and the second medium feed device is a low-pressure side heat exchanger of a refrigeration cycle.

11. (canceled)

12. (canceled)

13. The device temperature regulator according to claim 8, wherein
the first condenser is connected to the first liquid-phase passage at a first position in the gravitation direction, lower than a second position where the second condenser is connected to the second liquid-phase passage, and
the first medium feed device and the second medium feed device are configured to set a temperature of the first medium fed to the first condenser lower than a temperature of the second medium fed to the second condenser.

14. The device temperature regulator according to claim 8, wherein
the first condenser is connected to the first liquid-phase passage at a first position in the gravitation direction, lower than a second position where the second condenser is connected to the second liquid-phase passage,
the first medium feed device is a low-pressure side heat exchanger configuring the refrigeration cycle, and
the second medium feed device is a blower.

15. The device temperature regulator according to claim 1, wherein the first condenser and the second condenser are connected to each other in parallel with respect to the gas-phase passage.
